(19) United States
(12) Patent Application Publication
(10) Pub. No.: US 2025/0219357 A1
(43) Pub. Date: Jul. 3, 2025

(54) OPTOELECTRONIC COMPONENT

(71) Applicant: ams-OSRAM International GmbH, Regensburg (DE)

(72) Inventors: Tobias HAUPELTSHOFER, Breitenbrunn (DE); Jan MARFELD, Regensburg (DE); Jörg Erich SORG, Regensburg (DE); Andreas FRÖHLICH, Regensburg (DE); Sebastian SCHLEGL, Bad Abbach (DE)

(73) Assignee: ams-OSRAM International GmbH, Regensburg (DE)

(21) Appl. No.: 18/848,078

(22) PCT Filed: Feb. 13, 2023
(86) PCT No.: PCT/EP2023/053436

§ 371 Date: Sep. 17, 2024

(30) Foreign Application Priority Data
Mar. 24, 2022 (DE) 10 2022 106 948.6

(51) Int. Cl. H01S 5/40; H01S 5/02315

(52) U.S. Cl. CPC H01S 5/405; H01S 5/02315; H01S 5/4093

(57) ABSTRACT

The invention relates to an optoelectronic component, having a support and at least two lasers which are arranged on the support, wherein the surface area of a common beam outlet window of the optoelectronic component for the electromagnetic laser beam, which is generated during operation, of the at least two lasers equals at most 500×100 μm2 for an uncollimated electromagnetic laser beam or at most 1500×300 μm2 for a collimated electromagnetic laser beam.

### CROSS-REFERENCE TO RELATED APPLICATIONS

The present application is a national stage entry from International Application No. PCT/EP2023/053436, filed on Feb. 13, 2023, published as International Publication No. WO 2023/179967 A1 on Sep. 28, 2023, and claims priority to German Patent Application No. 10 2022 106 948.6, filed Mar. 24, 2022, the disclosures of all of which are hereby incorporated by reference in their entireties.

### FIELD

An optoelectronic component is specified.

### BACKGROUND

One object of at least certain embodiments is to provide an optoelectronic component with at least two emitters, wherein the optoelectronic component comprises a particularly small radiation exit window.

### SUMMARY

According to at least one embodiment, the optoelectronic component comprises a carrier. In particular, the carrier is configured for mechanically stabilizing the optoelectronic component. Furthermore, the carrier configured for dissipating heat generated during operation, for example.

For example, the carrier comprises a ceramic material or a metal, or consists of a ceramic material or a metal. The carrier can comprise electric contact areas.

The carrier comprises a main surface that extends in lateral directions. A direction perpendicular to the main surface of the carrier is subsequently also referred to as vertical direction. In particular, the vertical direction is therefore perpendicular to the lateral directions.

According to at least one further embodiment, the optoelectronic component comprises at least two lasers arranged on the carrier. For example, the lasers are arranged on the main surface of the carrier. The at least two lasers can be electrically contacted via contact areas on the carrier.

In particular, a laser includes an optically active region and an optical resonator. In the optically active region, for example, electrical energy is converted into electromagnetic radiation. Together with the active region, the optical resonator is in particular configured for generating electromagnetic laser radiation.

Electromagnetic laser radiation is generated by stimulated emission. In contrast to electromagnetic radiation that is generated by spontaneous emission, electromagnetic laser radiation has a longer coherence length, a narrower spectral line width and/or a higher degree of polarization.

For example, the at least two lasers are configured for emitting electromagnetic laser radiation in a spectral range between infrared and ultraviolet light. The lasers can emit electromagnetic laser radiation in the same spectral range or in different spectral ranges.

The lasers are preferably realized as laser diodes or comprise laser diodes. In particular, laser diodes comprise an epitaxial semiconductor layer stack. The active region is, for example, a p-n junction including at least one p-doped semiconductor layer and one n-doped semiconductor layer.

The at least two lasers can preferably be operated independently of each other. For example, an intensity of the electromagnetic laser radiation emitted by different lasers can be adjusted independently of each other.

The electromagnetic laser radiation generated by the at least two lasers during operation is emitted, for example, in a lateral direction, i.e. parallel to the main surface of the carrier. It is also possible that the electromagnetic laser radiation generated during operation is emitted in vertical direction.

According to at least one further embodiment, an area of a common radiation exit window of the optoelectronic component for electromagnetic laser radiation generated during operation by the at least two lasers is at most 500×100 μm² for uncollimated electromagnetic laser radiation, or at most 1500×300 μm² for collimated electromagnetic laser radiation. Preferably, the area of the radiation exit window is at most 250×50 μm² for uncollimated electromagnetic laser radiation, or at most 1000×200 μm² for collimated electromagnetic laser radiation. In particular, the radiation exit window is a continuous surface via which electromagnetic laser radiation generated during operation is coupled out of the optoelectronic component. Preferably, electromagnetic laser radiation generated during operation by the at least two lasers is decoupled from the optoelectronic component exclusively via the radiation exit window.

Here and in the following, collimated electromagnetic laser radiation refers in particular to electromagnetic laser radiation that has passed through collimation optics. The collimation optics is configured, for example, for reducing a beam divergence of the electromagnetic laser radiation. By contrast, here and in the following electromagnetic laser radiation is referred to as uncollimated, if the electromagnetic laser radiation has not passed through collimation optics for reducing the beam divergence.

The radiation exit window is part of an encapsulation of the optoelectronic component, for example. The encapsulation can be configured for protecting the lasers in the optoelectronic component from harmful environmental influences. In particular, the radiation exit window includes a material that is at least partially transparent to the electromagnetic laser radiation generated during operation. For example, a transmissivity of the radiation exit window is at least 80%, preferably at least 90%, for the electromagnetic radiation generated during operation. For example, the radiation exit window comprises a glass.

The lasers can also be individually encapsulated on the carrier, or the optoelectronic component may comprise no encapsulation. In this case, the radiation exit window is, for example, an imaginary, continuous surface that is penetrated by the electromagnetic radiation generated during operation when it is decoupled from the optoelectronic component.

For example, the radiation exit window has a rectangular shape and comprises a width of at most 500 μm and a height of at most 100 μm for uncollimated electromagnetic laser radiation, or a width of at most 1500 μm and a height of at most 300 μm for collimated electromagnetic laser radiation. Preferably, the width is at most 250 μm and the height at most 50 μm for uncollimated electromagnetic laser radiation. For collimated electromagnetic laser radiation, the width is preferably at most 1000 μm and the height is preferably at most 200 μm. The width denotes, for example, a spatial extension of the radiation exit window in a lateral direction, while the height denotes, for example, a spatial extension of the radiation exit window in vertical direction. The radiation exit window can also comprise a round, oval or polygonal shape.

According to a preferred embodiment, the optoelectronic component includes:
the carrier, and
at least two lasers arranged on the carrier, wherein
the area of the common radiation exit window for the electromagnetic laser radiation generated during operation by the at least two lasers is at most 500×100 μm² for uncollimated electromagnetic laser radiation, or at most 1500×300 μm² for collimated electromagnetic laser radiation.

In virtual reality (short: VR) or augmented reality (short: AR) applications laser projectors are used to display images, for example. A particularly compact laser package is advantageous in order to be able to manufacture VR glasses or AR glasses that are as compact, i.e. small and light, as possible.

In a laser package with several lasers arranged laterally next to each other that emit electromagnetic laser radiation in the same direction, the width of the radiation exit window is determined, for example, by a total width of all the lasers. The width of the radiation exit window therefore increases linearly with the number of lasers. For example, several lasers are arranged next to each other to display different colors. As a result, the laser package may comprise an unfavorably large width.

In particular, the optoelectronic component described herein is based on the idea of arranging several lasers on the carrier in such a way that the electromagnetic laser radiation generated by all lasers during operation is decoupled from the optoelectronic component via a radiation exit window that is as small as possible. The optoelectronic component is advantageously compact and suitable for VR and/or AR applications, for example.

According to at least one further embodiment, the at least two lasers are arranged on the carrier such that each laser comprises an identical emission direction for electromagnetic laser radiation generated during operation. In other words, the electromagnetic laser radiation generated during operation by the at least two lasers is emitted parallel to each other. In particular, the emission direction indicates a main direction in which the electromagnetic laser radiation of a laser is emitted. For example, the emission direction corresponds to the direction of an optical axis of the optical resonator.

According to at least one further embodiment, at least one laser comprises an edge-emitting laser diode. In edge-emitting laser diodes, electromagnetic laser radiation is preferably emitted via a side surface of the semiconductor layer stack. In particular, the optical axis of the optical resonator is arranged parallel to a main extension plane of semiconductor layers of the semiconductor layer stack.

Alternatively or additionally, at least one laser can be realized as a vertical cavity surface emitting laser diode (short: VCSEL). In contrast to an edge-emitting laser diode, electromagnetic laser radiation is preferably emitted via a main surface of the semiconductor layer stack in a vertical cavity surface emitting laser diode. In particular, the optical axis of the optical resonator is arranged perpendicular to the main extension plane of semiconductor layers of the semiconductor layer stack.

According to at least one further embodiment, a radiation outcoupling surface of at least one laser comprises a plurality of emission points. Here and in the following, an emission point refers in particular to a point on a radiation outcoupling surface of the laser from which the electromagnetic laser radiation generated during operation is emitted.

Furthermore, the emission point can also designate an emission region on the radiation outcoupling surface. For example, the emission region is determined by a mode profile of the electromagnetic laser radiation on the radiation outcoupling surface of the laser. In particular, the mode profile denotes an intensity distribution of the electromagnetic laser radiation in directions perpendicular to the emission direction.

For example, the laser is a laser bar or an edge-emitting laser diode whose semiconductor layer stack comprises at least two parallel ridge waveguides. In particular, the ridge waveguide is configured for confining electromagnetic laser radiation in the region of the optical resonator. For example, each ridge waveguide comprises an associated optical resonator and thus an associated emission point on the side surface of the semiconductor layer stack.

According to at least one further embodiment, each laser comprises collimation optics, respectively. In particular, the collimation optics comprises one or more optical lenses and is configured, for example, to reduce a beam divergence of the electromagnetic laser radiation emitted by the laser. The beam divergence describes, in particular, a widening of the electromagnetic laser radiation in the emission direction. For example, the beam divergence indicates an angular range within which the electromagnetic laser radiation is emitted.

The beam divergence can be different in different directions perpendicular to the emission direction. For example, the mode profile of the electromagnetic laser radiation comprises two main axes, wherein the beam divergence along one main axis is maximal (fast-axis), while the beam divergence along the other main axis is minimal (slow-axis). In particular, the collimation optics is configured for collimating the electromagnetic laser radiation at least along the fast-axis. In addition, the collimation optics can be configured for collimating the electromagnetic laser radiation along the slow-axis.

The collimation optics can be arranged directly on the radiation outcoupling surface of the laser or at a distance from the radiation outcoupling surface. A collimation optics arranged directly on the radiation outcoupling surface is configured to protect the radiation outcoupling surface from harmful deposits, for example.

According to at least one further embodiment the collimation optics of the lasers are configured such that electromagnetic laser radiation generated during operation by different lasers does not overlap in the radiation exit window. In particular, beam waists of the electromagnetic laser radiation generated during operation by different lasers do not overlap in the radiation exit window.

For example, the electromagnetic laser radiation emitted by a laser comprises a mode profile with a beam waist. In particular, the beam waist denotes a distance from a beam axis at which the intensity of the electromagnetic laser radiation has decreased by 63%, for example, compared to the intensity on the beam axis. By avoiding an overlap of electromagnetic laser radiation in the radiation exit window, possible interference between the electromagnetic laser radiation of different lasers is advantageously reduced.

According to at least one further embodiment, the collimation optics of at least one laser is configured for rotating a polarization direction of the electromagnetic laser radiation generated during operation. For example, the collimation optics includes a birefringent material, in particular a retardation plate, which can rotate the polarization direction by a predetermined angle, for example.

According to at least one further embodiment, the optoelectronic component comprises at least two lasers that emit electromagnetic laser radiation in different spectral ranges. For example, the at least two lasers emit electromagnetic laser radiation of different colors.

Alternatively or additionally, at least two lasers can also emit electromagnetic laser radiation in the same spectral range. For example, this can increase the output power of the optoelectronic component.

The spectral ranges of the at least two lasers can also be slightly shifted relative to each other. For example, the spectral ranges are shifted relative to each other by one full width at half maximum of a spectrum of the electromagnetic laser radiation generated during operation. As a result, the electromagnetic laser radiation emitted by the optoelectronic component comprises, for example, an increased spectral width compared to the electromagnetic laser radiation of a single laser.

According to at least one further embodiment, the optoelectronic component comprises a red laser, a green laser and a blue laser, wherein the red laser emits electromagnetic laser radiation in a red spectral range, the green laser emits electromagnetic laser radiation in a green spectral range, and the blue laser emits electromagnetic laser radiation in a blue spectral range. The red spectral range includes, for example, wavelengths between 600 nm and 780 nm, inclusive. The green spectral range includes, for example, wavelengths between 500 nm and 570 nm, inclusive. The blue spectral range includes, for example, wavelengths between 430 nm and 490 nm, inclusive. Thus, the optoelectronic component is configured for full-color laser projection applications, for example.

According to at least one further embodiment, the optoelectronic component comprises a first laser, a second laser and a third laser, wherein the first laser and the second laser are arranged laterally next to one another on a main surface of the carrier, the third laser is arranged in an emission direction behind the first laser and behind the second laser, and an emission point of the third laser is arranged in a vertical direction perpendicular to the main surface of the carrier above the first laser and above the second laser. Preferably, the first laser, the second laser and the third laser comprise the same emission direction. Here and in the following, an arrangement of the third laser in the emission direction “behind” the first laser or “behind” the second laser means that the first laser or the second laser is arranged downstream of the third laser in the emission direction.

In particular, the third laser is arranged such that the electromagnetic laser radiation emitted by the third laser does not hit the first and second lasers arranged in front of the third laser in the emission direction. In particular, this arrangement of the third laser makes it possible to reduce the width of the radiation exit window.

According to at least one further embodiment, a lateral distance between emission points of the first laser and the second laser is smaller than a lateral distance between geometric centers of the first laser and the second laser. Preferably, the lateral distance between emission points of the first laser and the second laser is at least 20% smaller than a lateral distance between geometric centers of the first laser and the second laser. Particularly preferably, the lateral distance between emission points of the first laser and the second laser is at least 40% smaller than a lateral distance between geometric centers of the first laser and the second laser. In particular, the lateral distance refers to a distance in a lateral direction perpendicular to the emission direction of the first laser and/or the second laser.

For example, laser diodes of the first laser and the second laser have widths of approximately 300 μm, wherein the width denotes a lateral spatial extension of the laser perpendicular to the emission direction. For example, the first laser and the second laser are arranged at a lateral distance of approximately 30 μm. Thus, the lateral distance between the geometric centers of the first laser and the second laser is approximately 330 μm. By contrast, the lateral distance between the emission points is, for example, at most 90 μm.

In particular, the emission points of the first laser and the second laser are arranged as close as possible to edges of the associated radiation outcoupling surfaces that face each other. This advantageously reduces the width of the radiation exit window, for example.

According to at least one further embodiment, the main surface of the carrier is structured so that the carrier comprises a smaller thickness at locations where the first laser and the second laser are arranged than at a location where the third laser is arranged. Here and in the following the thickness refers to a spatial extension in vertical direction. In particular, the third laser is thereby arranged offset from the first and second lasers in the vertical direction. In particular, a vertical distance between the emission point of the third laser and the emission points of the first and second lasers can be set by adjusting the thicknesses of the carrier.

According to at least one further embodiment, a base is arranged between the main surface of the carrier and the third laser, so that the third laser is spaced from the main surface in the vertical direction. In particular, a vertical distance between the main surface and the third laser is larger than a vertical distance between the main surface and the first laser and/or the second laser. Thus, in particular, a vertical distance between the emission point of the third laser and the emission points of the first and second lasers can be set.

According to at least one further embodiment, a base is arranged between the main surface of the carrier and the first laser and/or the second laser. In particular, a base can be arranged between the main surface of the carrier and each of the lasers. Thicknesses of the bases are preferably selected such that lasers arranged downstream in the emission direction comprise a base with a smaller thickness. For example, the thickness of the base of the third laser is larger than the thickness of the base of the first laser and/or larger than the thickness of the base of the second laser.

According to at least one further embodiment, the optoelectronic component comprises a fourth laser which is arranged laterally next to the third laser, wherein an emission point of the fourth laser is arranged in the vertical direction above the first laser and above the second laser. For example, the third laser and the fourth laser are arranged offset in the vertical direction compared to the first laser and the second laser. In particular, the first laser and the second laser are arranged downstream of the third laser and the fourth laser in the emission direction.

According to at least one further embodiment, the third laser and the fourth laser comprise a common collimation optics. In particular, the third laser and the fourth laser have the same emission direction. Preferably, the emission points of the third and fourth lasers are arranged as close as possible to facing edges of the associated radiation outcoupling surfaces. Thus, for example, a lateral distance between electromagnetic laser radiation of the third laser and electromagnetic laser radiation of the fourth laser is particularly small, so that a common collimation optics can be used to collimate the electromagnetic laser radiation of the third and fourth lasers.

According to at least one further embodiment, the optoelectronic component further comprises an optical element configured for reducing a distance between parallel propagating electromagnetic laser radiation from different lasers. The optical element includes, for example, reflective and/or diffractive elements.

For example, the optical element comprises waveguides and/or is designed as a planar light circuit (short: PLC). Therein, for example, at least two waveguides for electromagnetic laser radiation are incorporated into a carrier material such that the distance between electromagnetic laser radiation propagating in parallel is reduced. Furthermore, the optical element may comprise a photonic integrated circuit (short: PIC). In addition to passive elements, a photonic circuit can also include active elements. Passive elements are, for example, waveguides, while active elements are configured for light amplification, for example.

According to at least one further embodiment, the optical element includes a staircase mirror comprising staggered reflective surfaces. For example, a reflective surface is assigned to each laser and vice versa. In other words, the reflective surfaces are arranged in such a way that only the electromagnetic laser radiation of the associated laser is incident on each reflective surface. In particular, the reflective surfaces are arranged parallel to each other. Electromagnetic laser radiation incident in parallel is thus deflected by the staircase mirror and then propagates further in parallel.

Preferably, the reflective surfaces are staggered such that they are spaced apart in a direction perpendicular to the reflective surfaces. By suitably selecting a distance between the reflective surfaces, it is thus possible to change, in particular, a distance between parallel propagating electromagnetic laser radiation which is coupled out of the staircase mirror.

Further, a VR goggle and/or an AR goggle is specified. The VR goggle and/or the AR goggle are, in particular, a portable optoelectronic device that is configured, for example, for the visual display of information in the form of images or pictograms.

According to one embodiment, the VR goggle and/or the AR goggle comprises an optoelectronic component as described herein. In addition, the VR goggle and/or the AR goggle comprises, for example, a projection surface. The projection surface can be at least partially transparent to external light. In particular, the optoelectronic component is configured as a light source for the visual display of information on the projection surface.

Further advantageous embodiments and further developments of the optoelectronic component follow from the exemplary embodiments described below in conjunction with the figures.

### BRIEF DESCRIPTION OF THE DRAWINGS

FIGS. 1, 2 and 3 show various schematic views of an optoelectronic component according to an exemplary embodiment.

FIGS. 4, 5 and 6 show various schematic views of an optoelectronic component according to a further exemplary embodiment.

FIG. 7 shows a schematic view of an optoelectronic component according to a further exemplary embodiment.

FIGS. 8 and 9 show various schematic views of an optoelectronic component according to a further exemplary embodiment.

FIGS. 10 and 11 show various schematic views of an optoelectronic component according to a further exemplary embodiment.

### DETAILED DESCRIPTION

Elements that are identical, similar or have the same effect are marked with the same reference signs in the figures. The figures and the proportions of the elements shown in the figures are not to be regarded as being true to scale. Rather, individual elements may be shown in exaggerated size for better visualization and/or understanding.

FIG. 1 shows a schematic top view of an exemplary embodiment. In particular, the optoelectronic component includes a carrier 5 with a main surface 10 on which a first laser 1, a second laser 2 and a third laser 3 are arranged. In particular, a top view of the main surface 10 of the carrier 5 is shown.

The first laser 1, the second laser 2 and the third laser 3 are realized as edge-emitting laser diodes comprising the same emission direction R. In particular, electromagnetic laser radiation 13 generated during operation by the three lasers 1, 2, 3 is emitted in a lateral direction parallel to the main surface 10 of the carrier 5. For example, the first laser 1 emits electromagnetic laser radiation 13 in the red spectral range, while the second laser 2 emits electromagnetic laser radiation 13 in the blue spectral range and the third laser 3 emits electromagnetic laser radiation 13 in the green spectral range.

The third laser 3 is arranged behind the first laser 1 and the second laser 2 in emission direction R. In other words, the first laser 1 and the second laser 2 are arranged downstream of the third laser 3 in the emission direction R.

An emission point 8 of the third laser 3 is arranged in a lateral direction perpendicular to the emission direction R between the first laser 1 and the second laser 2.

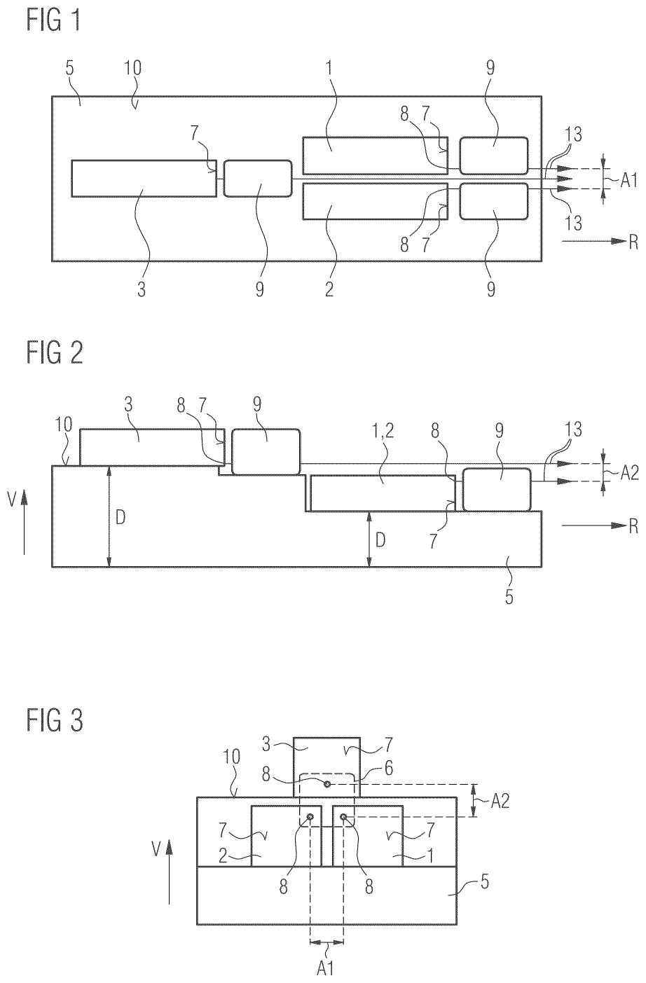

To ensure that the electromagnetic laser radiation 13 of the third laser 3 generated during operation does not hit the first laser 1 and the second laser 2, the third laser 3 is arranged offset in vertical direction V relative to the first laser 1 and the second laser 2 (see FIGS. 2 and 3). In particular, the emission point 8 of the third laser 3 is located in the vertical direction V above a highest point of the first laser 1 and above a highest point of the second laser 2. This arrangement is particularly advantageous if a distance between the first laser 1 and the second laser 2 is so small that the electromagnetic laser radiation of the third laser 3 cannot propagate undisturbed through a gap between facing side surfaces of the first laser 1 and the second laser 2.

A lateral distance A1 between the emission points 8 of the first laser 1 and the second laser 2 is, in particular, smaller than a lateral distance between geometric centers of the first laser 1 and the second laser 2. The emission point 8 of the first laser 1 is arranged as close as possible to an edge of the radiation outcoupling surface 7 facing the second laser 2. Furthermore, the emission point 8 of the second laser 2 is arranged as close as possible to an edge of the radiation outcoupling surface 7 facing the first laser 1. Thus, the radiation exit window 6 (not shown here, see FIG. 3) advantageously comprises a small width in the lateral direction.

The first laser 1, the second laser 2 and the third laser 3 each comprise their own collimation optics 9. The collimation optics 9 are arranged downstream of the lasers 1, 2, 3 in the emission direction R and are configured for reducing a beam divergence of the electromagnetic laser radiation 13 generated during operation. For example, the collimation optics 9 comprises one or more optical lenses.

FIG. 2 shows a schematic side view of the optoelectronic component according to the exemplary embodiment described in connection with FIG. 1. The main surface 10 of the carrier 5 is structured such that the carrier 5 comprises a larger thickness D in a region where the third laser 3 is arranged than in a region where the first laser 1 and the second laser 2 are arranged. Accordingly, the third laser 3 is offset in the vertical direction V in relation to the first laser 1 and the second laser 2. Alternatively or in addition to the structured main surface 10, the third laser 3 can also be arranged on a base 14 having a corresponding thickness (not shown).

The emission points 8 of the first laser 1 and the second laser 2 are arranged in the vertical direction V as close as possible to a top side of the first laser 1 and the second laser 2, respectively. The emission point 8 of the third laser 3 is arranged in such a way that the electromagnetic laser radiation 13 propagates as close as possible above the first laser 1 and the second laser 2. In particular, the emission point 8 of the third laser is arranged as close as possible to an edge of the radiation outcoupling surface 7 facing the main surface 10 of the carrier 5. Thus, a vertical distance A2 between the emission point 8 of the third laser 3 and the emission points 8 of the first laser 1 and the second laser 2 is advantageously reduced. As a result, the radiation exit window 6 (not shown here, see FIG. 3) comprises an advantageously small height in the vertical direction V.

It is also possible that the third laser 3 is not arranged completely above the first laser 1 and above the second laser 2 in vertical direction V, but only partially projects above the first laser 1 and the second laser 2 in vertical direction V, for example. In this case, the emission point 8 of the third laser 3 is preferably arranged above the first laser 1 and above the second laser 2 in the vertical direction V, so that the vertical distance A2 between the emission points 8 is as small as possible.

FIG. 3 shows a schematic front view of the optoelectronic component according to the exemplary embodiment described in connection with FIGS. 1 and 2. In particular, a view against the emission direction R of the radiation outcoupling surfaces 7 of the three lasers 1, 2, 3 is shown. For better visualization, the collimation optics 9 are not shown here.

The radiation exit window 6 is marked by a dashed line and is essentially determined by the lateral distance A1 and the vertical distance A2 of the emission points 8 of the first laser 1, the second laser 2, and the third laser 3. Due to the spatial arrangement of the three lasers 1, 2, 3, and due to the emission points 8 being arranged as close as possible to the respective radiation outcoupling surface 7 of the three lasers 1, 2, 3, the radiation exit window 6 advantageously comprises a small area.

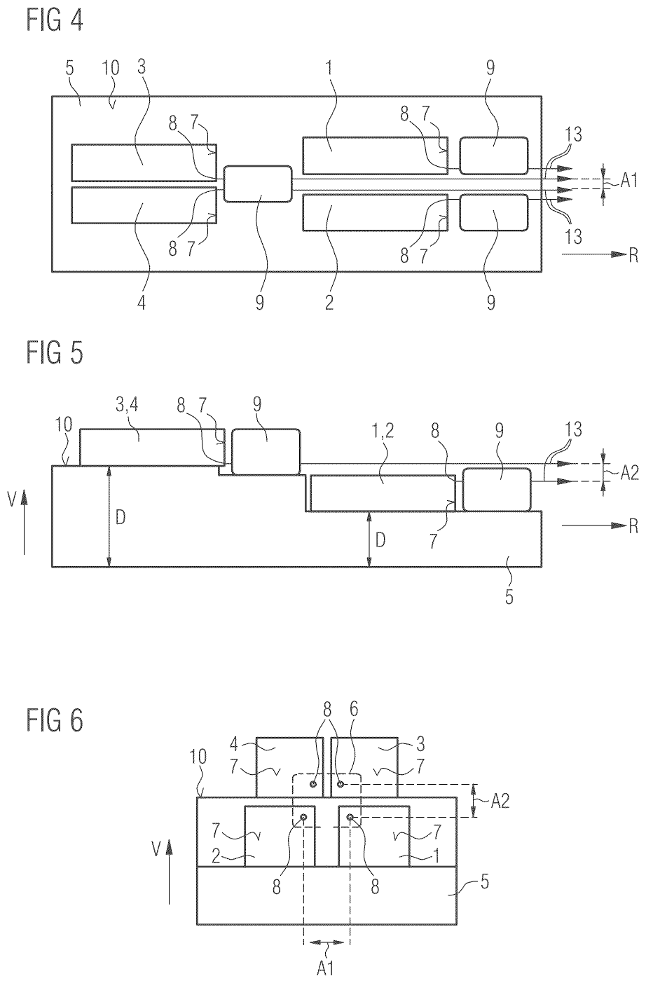

FIG. 4 shows a schematic top view of an optoelectronic component according to a further exemplary embodiment which, in contrast to the exemplary embodiment in FIG. 1, comprises an additional fourth laser 4. The fourth laser 4 is arranged laterally next to the third laser 3 and has the same emission direction R as the first laser 1, the second laser 2 and the third laser 3. For example, the fourth laser 4 emits electromagnetic laser radiation 13 in the same spectral range or in a similar spectral range as the third laser 3. Preferably, the laser diodes of the third laser 3 and the fourth laser 4 have the same or a similar beam divergence.

A lateral distance A1 between the emission points 8 of the third laser 3 and the fourth laser 4 is as small as possible and, in particular, smaller than a lateral distance between geometric centers of the third laser 3 and the fourth laser 4. The emission points 8 of the third laser 3 and the fourth laser 4 are arranged as close as possible to facing edges of the radiation outcoupling surfaces 7.

Due to the small lateral distance A1 between the emission points 8 of the third laser 3 and the fourth laser 4, separate collimation optics 9 for the third laser 3 and the fourth laser 4 can be dispensed with. The third laser 3 and the fourth laser 4 therefore comprise a common collimation optics 9.

FIG. 5 shows a side view of the optoelectronic component according to the exemplary embodiment described in connection with FIG. 4. In particular, the carrier 5 comprises a larger thickness D in a region in which the third laser 3 and the fourth laser 4 are arranged than in a region in which the first laser 1 and the second laser 2 are arranged.

The emission points 8 of the lasers 1, 2, 3, 4 are arranged, in particular, such that the vertical distance A2 between the emission points 8 is as small as possible.

FIG. 6 shows a schematic front view of the optoelectronic component according to the exemplary embodiment described in connection with FIGS. 4 and 5. In particular, a view against the emission direction R of the radiation outcoupling surfaces 7 of the four lasers 1, 2, 3, 4 is shown. For better visualization, the collimation optics 9 are not shown here.

The advantageously small radiation exit window 6 is marked by a dashed line and is essentially determined by the lateral distance A1 and the vertical distance A2 of the emission points 8 of the first laser 1, the second laser 2, the third laser 3 and the fourth laser 4.

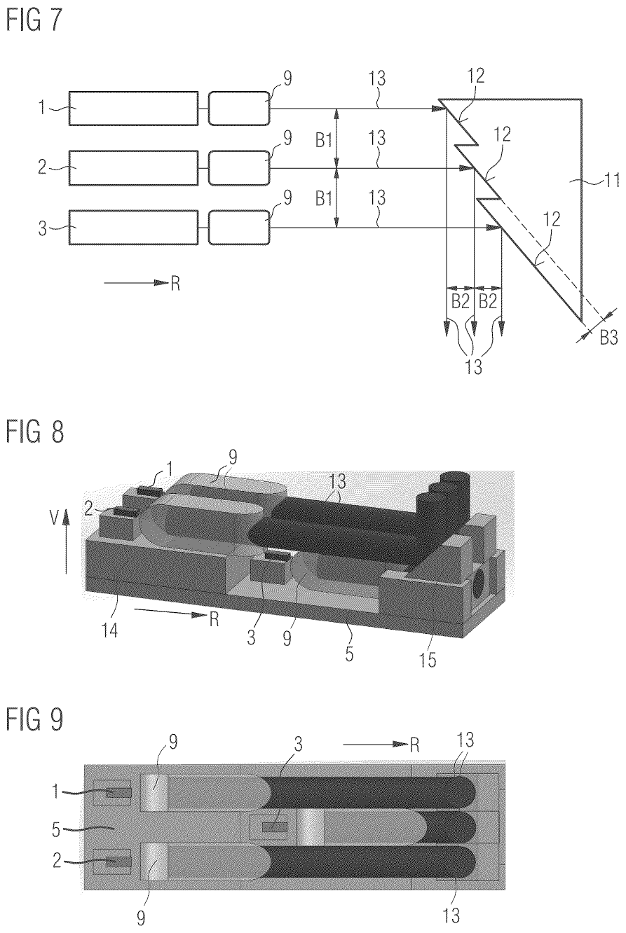

FIG. 7 shows an exemplary embodiment of an optoelectronic component comprising a first laser 1, a second laser 2 and a third laser 3 with associated collimation optics 9. The lasers 1, 2, 3 are arranged on a carrier 5 (not shown) in such a way that they have the same emission direction R. In particular, electromagnetic laser radiation 13 from the three lasers 1, 2, 3 propagates parallel to each other in one plane. A distance B1 between electromagnetic laser radiation of the first laser 1 and the second laser 2, or between electromagnetic laser radiation of the second laser 2 and the third laser 3, is determined by a geometric arrangement of the lasers 1, 2, 3 on the carrier 5.

Furthermore, the optoelectronic component comprises an optical element 11, which is arranged downstream of the collimation optics 9 in the emission direction R. The optical element 11 is, in particular, a staircase mirror 11 comprising reflective surfaces 12. Each laser 1, 2, 3 is assigned exactly one reflective surface 12, wherein only the electromagnetic laser radiation 13 of the associated laser 1, 2, 3 is incident on the corresponding reflective surface 12. The reflective surfaces 12 are arranged parallel to each other and configured for deflecting incident laser radiation 13. For example, the electromagnetic laser radiation 13 is deflected by the staircase mirror 11 by 90 degrees and then further propagates parallel to each other.

The reflective surfaces 12 are not arranged in a plane, but comprise a distance B3 in a direction perpendicular to the reflective surfaces 12. In particular, by suitably selecting the distance B3, a distance B2 between the electromagnetic laser radiation 13 deflected by the staircase mirror 11 can be set. In particular, the distance B2 is reduced compared to the distance B1 of the incident electromagnetic laser radiation 13, i.e. B2<B1. Thus, a radiation exit window downstream of the staircase mirror 11 preferably comprises a smaller width.

FIG. 8 shows a schematic perspective view of an optoelectronic component according to an exemplary embodiment, comprising a first laser 1, a second laser 2 and a third laser 3 arranged on a carrier 5. All three lasers 1, 2, 3 comprise the same emission direction R for electromagnetic laser radiation 13 generated during operation.

The third laser 3 is arranged downstream of the first laser 1 and the second laser 3 in the emission direction R. The first laser 1 and the second laser 2 are arranged laterally next to each other on a base 14. Due to the base 14, the first laser 1 and the second laser 2 are arranged above the third laser 3 in the vertical direction V.

Each of the three lasers 1, 2, 3 comprises an associated collimation optics 9. The collimation optics 9 are configured, in particular, for reducing a beam divergence in two directions perpendicular to the emission direction R.

Furthermore, the optoelectronic component in FIG. 8 comprises optical deflection elements 15 which deflect the electromagnetic laser radiation 13 from the emission direction R into the vertical direction V. The optical deflection elements 15 are arranged, in particular, such that the deflected electromagnetic laser radiation 13 of the three lasers 1, 2, 3 propagates in one plane.

FIG. 9 shows a schematic top view of the optoelectronic component according to the exemplary embodiment described in connection with FIG. 8. In particular, the third laser 3 is arranged laterally perpendicular to the emission direction R between the first laser 1 and the second laser 2. Due to the vertically offset arrangement of the three lasers 1, 2, 3, the lateral distance between the lasers 1, 2, 3 can be advantageously reduced, for example.

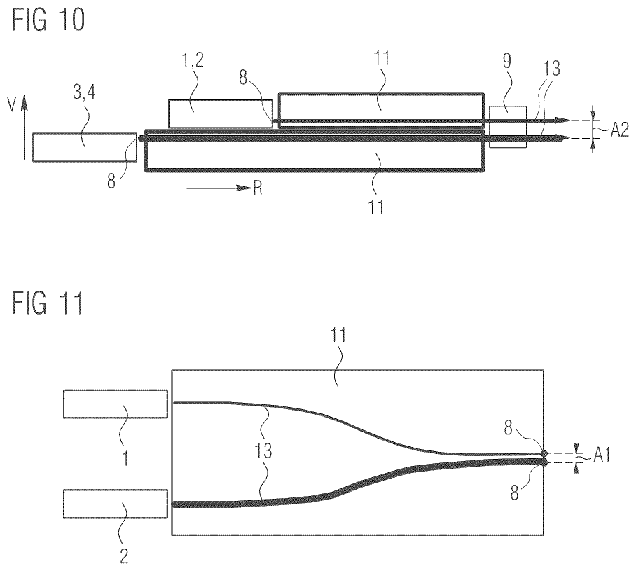

FIG. 10 shows a schematic side view of an optoelectronic component according to an exemplary embodiment, comprising four lasers 1, 2, 3, 4 with the same emission direction R. The first laser 1 and the second laser 2 are arranged laterally next to each other. Similarly, the third laser 3 and the fourth laser 4 are arranged laterally next to each other.

The first laser 1 and the second laser 2 are arranged downstream of the third laser 3 and the fourth laser 4 in the emission direction R. Furthermore, the first laser 1 and the second laser 2 are arranged above the third laser 3 and the fourth laser 4 in the vertical direction V, wherein a vertical distance A2 between the emission points 8 of the lasers 1, 2, 3, 4 is as small as possible.

An optical element 11 is arranged downstream of the first laser 1 and the second laser 2 in the emission direction R. The optical element 11 is a planar light circuit comprising two integrated waveguides. Similarly, a planar light circuit 11 is arranged downstream of the third laser 3 and the fourth laser 4 in the emission direction R. The planar light circuits are configured for reducing a lateral distance A1 between the emission points 8 of the first laser 1 and the second laser 2, or a lateral distance A1 between the emission points 8 of the third laser 3 and the fourth laser 4 (not shown, see FIG. 11). The electromagnetic laser radiation 13 coupled out of the planar light circuit 11 is further collimated by collimation optics 9.

FIG. 11 shows a schematic top view of the optoelectronic component according to the exemplary embodiment described in connection with FIG. 10. For better visualization, only the first laser 1, the second laser 2 and a planar light circuit 11 are shown. The planar light circuit 11 comprises two waveguides which are arranged in such a way that the lateral distance A1 between the emission points of the two lasers 1, 2 is reduced. As a result, the optoelectronic component advantageously comprises a particularly small radiation exit window 6 (not shown).

The invention is not limited to the description based on the exemplary embodiments. Rather, the invention includes any new feature as well as any combination of features, which includes, in particular, any combination of features in the patent claims, even if this feature or combination itself is not explicitly stated in the patent claims or exemplary embodiments.

1. An optoelectronic component comprising:
a carrier, and
a first laser, a second laser and a third laser arranged on the carrier, wherein
the first laser and the second laser are arranged laterally next to one another on a main surface of the carrier,
the third laser is arranged in an emission direction behind the first laser and behind the second laser, and
an area of a common radiation exit window of the optoelectronic component for electromagnetic laser radiation generated during operation by the three lasers is at most 500×100 μm² for uncollimated electromagnetic laser radiation, or at most 1500×300 μm² for collimated electromagnetic laser radiation.

2. The optoelectronic component according to claim 1, wherein the first, the second, and the third lasers are arranged on the carrier such that each laser comprises an identical emission direction for electromagnetic laser radiation generated during operation.

3. The optoelectronic component according to claim 1, wherein at least one laser comprises an edge-emitting laser diode.

4. The optoelectronic component according to claim 1, wherein a radiation outcoupling surface of at least one laser comprises a plurality of emission points.

5. The optoelectronic component according to claim 1, wherein each laser comprises collimation optics, respectively.

6. The optoelectronic component according to claim 5, wherein the collimation optics of the lasers are configured such that electromagnetic laser radiation generated during operation by different lasers does not overlap in the radiation exit window.

7. The optoelectronic component according to claim 5, wherein the collimation optics of at least one laser is configured for rotating a polarization direction of the electromagnetic laser radiation generated during operation.

8. The optoelectronic component according to claim 1, wherein at least two lasers emit electromagnetic laser radiation in different spectral ranges.

9. The optoelectronic component according to claim 1, wherein
a red laser emits electromagnetic laser radiation in a red spectral range,
a blue laser emits electromagnetic laser radiation in a blue spectral range, and
a green laser emits electromagnetic laser radiation in a green spectral range.

10. The optoelectronic component according to claim 1, wherein an emission point of the third laser is arranged in a vertical direction perpendicular to the main surface of the carrier above the first laser and above the second laser.

11. The optoelectronic component according to claim 10, wherein a lateral distance between emission points of the first laser and the second laser is smaller than a lateral distance between geometric centers of the first laser and the second laser.

12. The optoelectronic component according to claim 10, wherein
the main surface of the carrier is structured so that the carrier comprises a smaller thickness at locations where the first laser and the second laser are arranged than at a location where the third laser is arranged, and/or
a base is arranged between the main surface of the carrier and the third laser, so that the third laser is spaced from the main surface in the vertical direction.

13. The optoelectronic component according to claim 10, additionally comprising a fourth laser arranged laterally next to the third laser, wherein an emission point of the fourth laser is arranged in the vertical direction above the first laser and above the second laser.

14. The optoelectronic component according to claim 13, wherein the third laser and the fourth laser comprise a common collimation optics.

15. The optoelectronic component according to claim 1, further comprising an optical element configured for reducing a distance between parallel propagating electromagnetic laser radiation from different lasers.

16. The optoelectronic component according to claim 15, wherein the optical element includes a staircase mirror comprising staggered reflective surfaces.

17. A virtual reality (VR) goggle comprising the optoelectronic component according to claim 1.

18. An augmented reality (AR) goggle comprising the optoelectronic component according to claim 1.
